(19) United States
(12) Patent Application Publication
(10) Pub. No.: US 2026/0126353 A1
(43) Pub. Date: May 7, 2026

(54) LINE-BASED END POINT DETECTION

(71) Applicant: FEI Company, Hillsboro, OR (US)

(72) Inventors: David Prentice, Hillsboro, OR (US); Jason Chen, Taiwan (CN)

(73) Assignee: FEI Company, Hillsboro, OR (US)

(21) Appl. No.: 19/353,965

(22) Filed: Oct. 9, 2025

Related U.S. Application Data
(60) Provisional application No. 63/715,366, filed on Nov. 1, 2024.

(51) Int. Cl. G01N 1/28; G06T 7/13; G06V 10/25

(52) U.S. Cl. CPC G01N 1/286; G06T 7/13; G06V 10/25; G06T 2207/10061

(57) ABSTRACT

Methods for preparing a sample for analysis by a charged particle microscope (for example by providing a lamella) include removing material from a surface of a sample to provide a newly exposed surface and determining a region of interest (ROI) on the newly exposed surface. A plurality of lines is formed on the newly exposed surface and material from a working surface of the sample, different from the newly exposed surface, is removed a plurality of times. The working surface is imaged a plurality of times to at least capture the plurality of lines and an endpoint is determined based on a relative spatial characteristic between two or more lines of the plurality of lines.

### CROSS REFERENCE TO RELATED APPLICATION

This application claims priority to U.S. Provisional Patent Application No. 63/715,366, filed Nov. 1, 2024, which is incorporated by reference herein.

### FIELD

The invention relates generally to end point detection. In particular, new applications of end point detection on back end (back end of line, BEOL) semiconductor chips/coupons.

### BACKGROUND

Sample preparation using charged particle microscopes, such as dual beam microscopes that include both an ion column and an electron column, typically results in nanometer thin lamellae that may be imaged in a transmission electron microscope, for example. Such preparation is delicate, especially for lamellas that are on the order of 10 nm thick after formation. Such lamellas are formed by using the ion beam to mill away material from both sides of the sample in order to obtain the thin lamella. However, knowing or determining when to cease milling is a critical aspect and difficult to do with electron-based images.

Line Indicated Termination (LIT), as described in U.S. Pat. No. 11,355,313B2, is an automated process used in AutoTEM for thinning lamellae. LIT marks (alpha marks, lambda marks, etc.) are milled and deposited (i.e. “placed”) on a chip surface prior to thinning. The marks are used during the thinning process to automatically endpoint a sample in AutoTEM (using a neural net or other process).

However, typically LIT is applied to front end of line (FEOL) endpoint/thinning where the structures are more uniform, accessible, and imageable, and therefore easier to apply the necessary lines.

The methods and apparatus described herein can utilize LIT for back end of line (BEOL) endpointing/thinning. The is surprising and unexpected because BEOL structures are tall and non-uniform, with the region of interest (ROI) obscured by surrounding materials.

Typically, with BEOL devices, LIT marks placed on the surface (the BEOL layer/large metal layer/upper metal layer/back metal layer) can be a vertical distance of multiple to tens of microns from the FEOL ROI. This results in the utility of the LIT lines to finely automatically endpoint being severely reduced.

An inverted lift-out orientation puts the LIT lines at the bottom of the lamella, exposing the LIT lines to curtaining; both inverted and top-down lift-out orientations can propagate a minor accidentally applied lift-out tilt into more than enough offset at the ROI to prevent accuracy.

The methods of the invention described herein allow precise location of the ROI, and decreasing curtaining on the face of the lamella caused by the surrounding materials.

### SUMMARY

This invention seeks to address at least some of these various problems by the provision of methods and uses as defined in the application.

Thus, the application provides a method for preparing a sample for analysis by a charged particle microscope (for example by providing a lamella), wherein the method comprises:
removing material from a surface of a sample to provide a newly exposed surface;
determining a region of interest (ROI) on the newly exposed surface of the sample;
forming a plurality of lines on the newly exposed surface of the sample;
removing, a plurality of times, material from a working surface of the sample, where the working surface of the sample is different than the newly exposed surface;
imaging the working surface, (i.e. the surface that has been newly exposed by removing material from the working surface), a plurality of times, the sample to at least capture the plurality of lines; and
determining an endpoint based on a relative spatial characteristic between two or more lines of the plurality of lines.

The application also provides an apparatus that at least includes an ion beam column coupled to provide an ion beam; an electron beam column coupled to provide an electron beam, a sample arranged to receive the ion and electron beams, and a controller coupled to control the ion and electron beams. The controller includes or is coupled to nontransitory computer readable medium storing instructions that, when executed by the controller, cause the apparatus to:
remove, with the ion beam, a surface of a sample to provide a newly exposed surface;
determine a region of interest on the newly exposed surface;
form, with the ion beam, a plurality of lines on the newly exposed surface of the sample;
remove, a plurality of times with the ion beam, material from a working surface of the sample, the working surface different than the top surface;
image, a plurality of times with the electron beam, the sample a plurality of times to at least capture the plurality of lines, each of the occurring plurality of times occurring between at least one removal step; and
determine an endpoint based on a relative spatial characteristic between two or more lines of the plurality of lines.

The foregoing and other features, and advantages of the disclosed approaches will become more apparent from the following detailed description, which proceeds with reference to the accompanying figures.

### BRIEF DESCRIPTION OF THE DRAWINGS

FIG. 1—Illustration of the structure of a sample that may be used in the method of the invention.

FIG. 2A—Illustration of an example orientation of the ion gun used in the method of the invention where the side of the sample (often called the “face”) (i.e. the side of sample perpendicular to the to the top surface of the sample) is perpendicular to the focused ion beam (FIB).

FIG. 2B—Illustration of an example orientation of the ion gun used in the method of the invention where either the top surface or the bottom surface (i.e. silicon substrate layer) is perpendicular to the FIB.

FIG. 3—Illustration of a charged particle microscope that may be used in the method of the invention.

FIG. 4—Illustration of how a fiducial and LIT marks may be applied to the device/sample/chunk in the method of the invention.

FIGS. 5A and 5B—Illustration of the utilisation of the relative spatial characteristic of the lines to determine an endpoint, such as the edge of the ROI.

FIGS. 6A and 6B—Illustration of line configurations that may be used in the disclosed methods.

### DETAILED DESCRIPTION

The detailed description illustrates, by way of example, not by way of limitation, the principles of the invention, in particular in the context of dual beam charged particle microscope implementing line-based endpoint detection techniques.

The techniques include formation of lines on a surface of a sample that are used to determine when to stop removing material from the sample, i.e., endpoint detection. Such lines may have a relative spatial characteristic that is monitored and measured to determine the process endpoint, such as a depth of the trench forming the lines, or a distance between multiple sets of lines meeting a condition. These techniques will be described in further detail below.

In the method of the invention defined herein, the method comprises the step of removing material from a surface of a sample to provide a newly exposed surface.

In the method of the invention, the sample may be an unmodified sample, i.e. a microchip that has not been previously milled, or the sample may be a segment of a microchip that has been previously milled and extracted from a microchip.

Where the sample has been previously milled from and extracted from a larger sample, such as a microchip, the sample may also be referred to as a chunk.

The sample, such as a microchip chunk, may be in any stage of development, including a partially produced microchip (e.g. a chip with FEOL up to metal layers, but not yet in a form ready for consumer usage), to a fully produced microchip.

Thus, the method of the invention may include a step of extracting a portion of the device (sample/chunk) from the device, and securing it to a grid (or dual lamella carrier holder DLCH);

Where the sample is one what has been previously milled and extracted from a larger sample, such as a microchip, line-based end point detection (LIT) may be used in the provision of this sample, for example as a pre-step in the method of the invention. The LIT process is explained in more detail below.

Removing material from a surface of the sample typically comprises milling (i.e. ion beam milling or ion beam assisted etching, or a combination thereof) material from the sample. The milling may be performed by any suitable means. However, typically, milling may be performed using a focused ion beam (FIB), where the ion source maybe a liquid metal ion source that typically provides a metal ion beam of gallium or the ion source may be a plasma-based ion source capable of providing ion beam formed of a variety of ions, such as Xenon, Oxygen, Nitrogen, Argon, etc.

The surface from which the material is removed from the sample will depend on the orientation of the sample with respect to the milling source.

For ease of reference, the sample surfaces in the application will be defined relative to their position in the initial sample, i.e. in the microchip from where the sample has been taken.

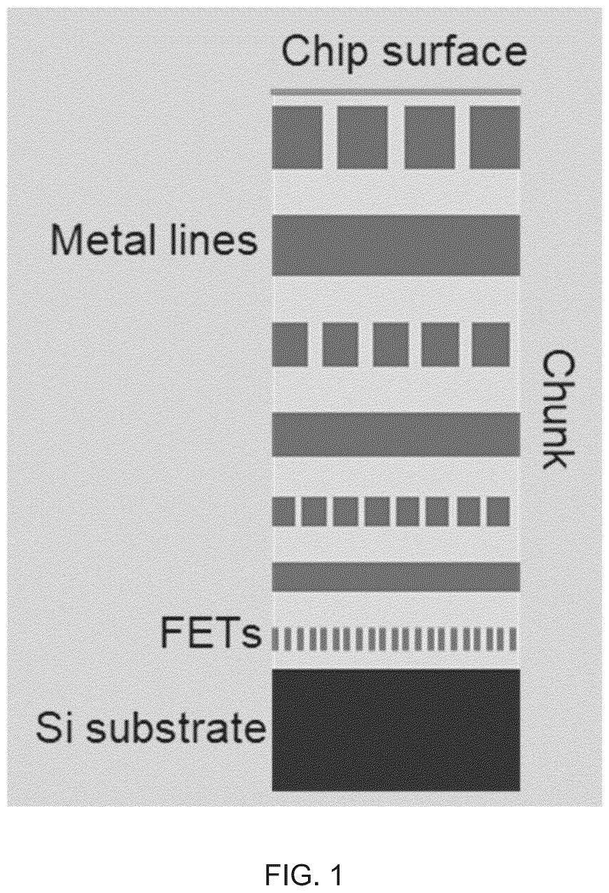

The sample, i.e. chunk, typically comprises a top surface and a bottom surface, wherein the top surface typically corresponds to the samples outer surface that lies distal to the bottom surface, typically this may be the surface layer of a microchip, wherein the bottom surface of the sample typically corresponds to the silicon substrate layer. This is shown in FIG. 1.

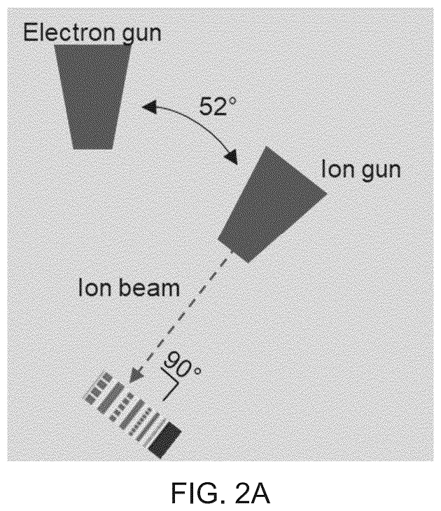

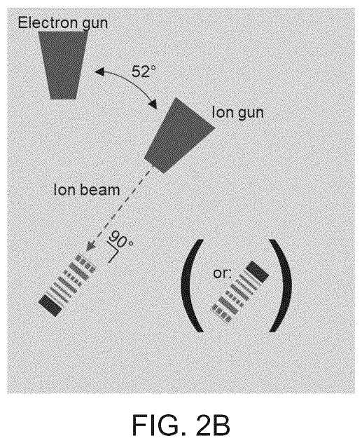

The sample may be positioned such that the side of the sample (often called the “face”) (i.e. the side of sample perpendicular to the to the top surface of the sample) is perpendicular to the focused ion beam (FIB) (as shown in FIG. 2A). Alternatively, the sample may be positioned such that either the top surface or the bottom surface (i.e. silicon substrate layer) is perpendicular to the FIB (as shown in FIG. 2B).

The positioning of the sample (chunk) may depend on the type of milling being performed.

For example, for delayering/deprocessing the sample (chunk), the beam typically impacts the sample (chunk) perpendicular (or at an angle close thereto) to the chunk face, and parallel to the chunk surface, and parallel to any BEOL metal lines.

This exposes a new surface parallel to the previous chunk surface that can be used to identify the ROI location. This can be done above or below the ROI, depending on the original device structure and lift-out orientation.

Where the milling is used for end-pointing and/or thinning the sample (chunk), the FIB typically impacts the chunk parallel (or at an angle close thereto) to the chunk face, and perpendicular to the chunk surface, and perpendicular to any BEOL metal lines; either impacting the chunk at the surface, or at the bottom of the sample.

Removing material exposes a new surface on the sample. As noted above, the newly exposed surface may run parallel to the original sample (chuck) surface, (i.e. the top surface), exposing subsurface device structures (FIG. 2A), or perpendicular to the original sample surface, exposing device structures perpendicular and cross sectional to alternative orientation (FIG. 2B).

After a new surface has been exposed, a regional of interest (ROI) is then determined on the newly exposed sample surface.

The determination of a ROI may be done manually, by relative position to features (i.e. a computer program finds a known feature and identifies the ROI in relative position to it), and/or by comparing/overlaying a map of the original device that the sample/chunk has been taken from.

For example, determining the region of interest may be accomplished by an offset method (programmatic or manual) where the ROI location is specified by its relative location to another feature. Programmatically this is often done with contrast measurement, where the metal lines are bright, the gaps are dark, and pairs can be counted to the desired region.

Alternatively, or additionally, determining the region of interest may be achieved by use of a map of the original device layers, such as a CAD map of the device layers with sufficient non-repeatability that the ROI location is distinct. The use of a CAD map, or other map of the device layers, may be automated such that a computer programme, i.e. a machine learning programme, has been trained to identify certain features on the map to locate ROI on the device that then can be used to identify ROIs on the sample/chunk. Alternatively, or additionally, the map may be reviewed manually and ROIs identified manually applied.

Once the ROI has been identified a plurality of lines can be formed on the newly exposed surface of the sample.

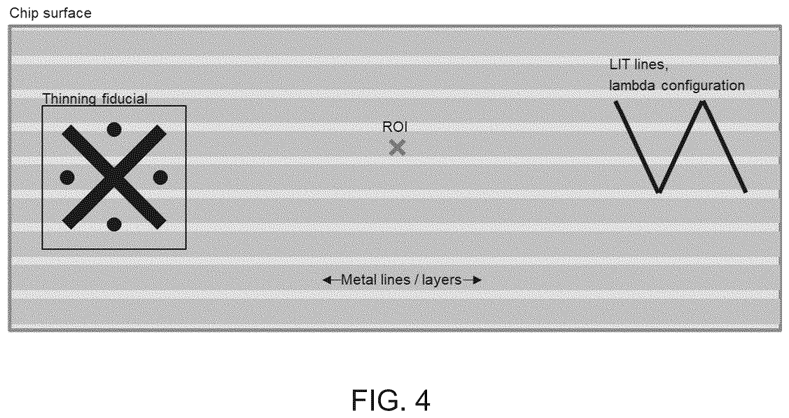

This may be performed using any suitable methods, such as those described in U.S. Pat. No. 11,355,313, herein incorporated by reference. However, it may be preferred that AutoTEM places the LIT lines relative to a fiducial and/or the origin (a defined position on the chunk, often the center in XYZ) in accordance to the ROI location as shown in FIG. 4.

Thus, the method of the invention may include placing a fiducial on the sample.

The LIT lines are offset (in X) from the ROI. The lines are milled with the FIB. Typically, the position in which the LIT lines are milled is as shown in FIG. 2B. However, other positions may also be used depending on the ROI to be imaged.

Milling the LIT lines may be performed at from about 10 kV to about 50 kV, preferably about 30 kV and at a low current such as from about 5 pA to about 50 pA, i.e. 7, 26, or 41 pA.

The lines are then delineated (meaning a very small dusting of deposition) and filed with a compound that will provide a contrast between the LIT lines and sample surface.

For example, the lines may be delineated with Tungsten (most often with FIB) and filled with TEOS (Tetraethyl orthosilicate) or Carbon (either in FIB or SEM). This typically provides the best contrast between the LIT lines and the sample/chuck while endpointing.

The plurality of lines includes two or more lines. For example, two, three, four, five, or six lines.

The number of lines used may depend on the type of sample and/or the ROI.

Preferred LIT line configurations are alpha and lambda.

Alpha (so called due to it looking vaguely like α) is composed of 5 mill lines and is placed centered (in Y) on a known ROI.

Lambda (so called due to it looking vaguely like λ) is composed of 3 mill lines.

Alpha is used primarily when an ROI is well located, such as on the FEOL, and allows thinning to be done without knowledge of the device/sample/chunk itself, with the automatic endpointer sampling only the LIT lines.

Lambda is used primarily for device/sample/chunk line neural net (DLNN) endpointing. The endpointer would check the device/sample/chunk structure until the front endpoint was reached, then check the current position relative to the LIT lines. For rear milling the opposite side would be rapidly milled to find the corresponding opposite side relative only to the LIT lines, and then implement DLNN endpointing, allowing quicker milling and less processing power.

For Chop & LIT, lambda marks take the place of the usual alpha use case. Lambda marks are placed centered (in Y) on the located ROI. The rationale here is that a CAD map can be applied again and any offset between the ROI location and the LIT mill can be compensated for. In this way the device/sample/chunk is thinned without further knowledge of the ROI structure, only utilizing the LIT lines.

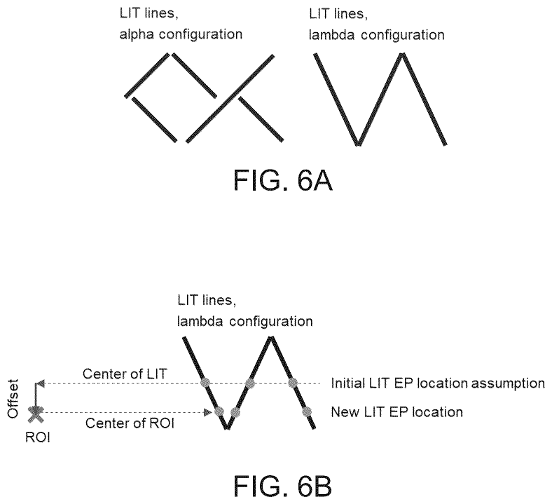

Examples of the line configurations that may be used in the method of the invention are shown in FIGS. 6A-6B.

The lines may be trenches milled into the surface or protrusions deposited on the top surface.

The lines may be arranged so that a relative spatial characteristic between at least two of the lines indicates an endpoint to material removal. The endpoint may be an edge of the lamella, but in other embodiments the endpoint may be an edge of the ROI.

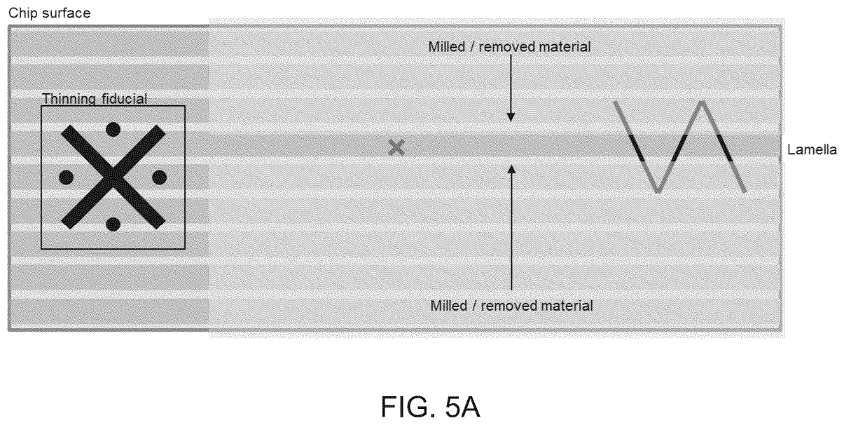

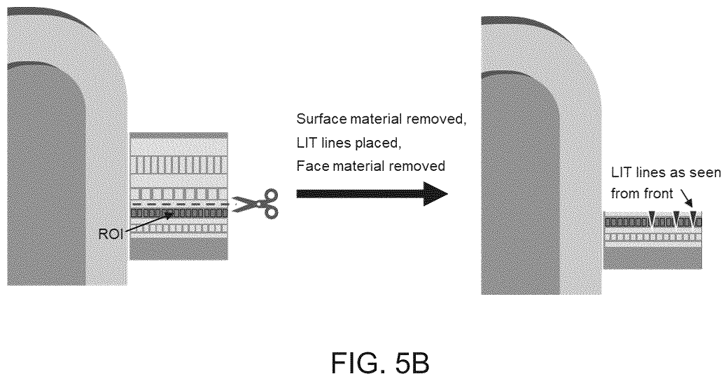

The relative spatial characteristic may be a distance between two or more of the lines, or a ratio of such distances. In both embodiments, however, the lines are formed on the top surface in such a way where the depths/heights or distances are aligned to a desired, pre-established endpoint, such as the edge of the ROI. This is shown in FIGS. 5A and 5B.

For example, two lines may be formed so that they are laterally offset and overlapping at their ends so that their depth, if they are trenches for example, are the same in an area of the sample desired to be the endpoint of sample processing.

Alternatively, the lines may be formed at different angles to one another and the changing distance between the lines may be monitored for a condition, such as equal distance. This equal distance indicates the endpoint to the process and is arranged with an edge of a region of interest, for example.

Such techniques aid in automation due to various characteristics of the techniques. For example, while the absolute depth of the lines will vary by sample material and beam shape, the depth of the lines should be equal at the line endpoints, providing a sample- and beam-insensitive reference point.

In this way this marking strategy is self-calibrating and leverages the high accuracy of the deflection system of the microscope. Additionally, SEM images collected during processing, e.g., thinning, can be run through a network/machine learning pipeline, a regular pattern match type machine-vision, and/or image processing algorithms to segment/identify and measure the lines. The segmented pixels can be analysed directly, or they can be used to place edge- or line-finders to measure the line depth. When the line depths match, the SW will tell the system to stop milling.

As noted above, after forming the plurality of lines on the newly exposed sample surface, material is removed from a working surface of the sample, where the working surface of the sample is different than the newly exposed surface.

The working surface may be at a normal angle to the newly exposed surface where the lines are formed, or some acute or obtuse angle thereto. The removal of the material may be by ion beam milling or ion beam assisted etching, or a combination thereof.

The energy of the ion beam may be adjusted as the working face moves closer to the desired endpoint, such as from 30 keV down to 0.5.

Images are acquired of the working face.

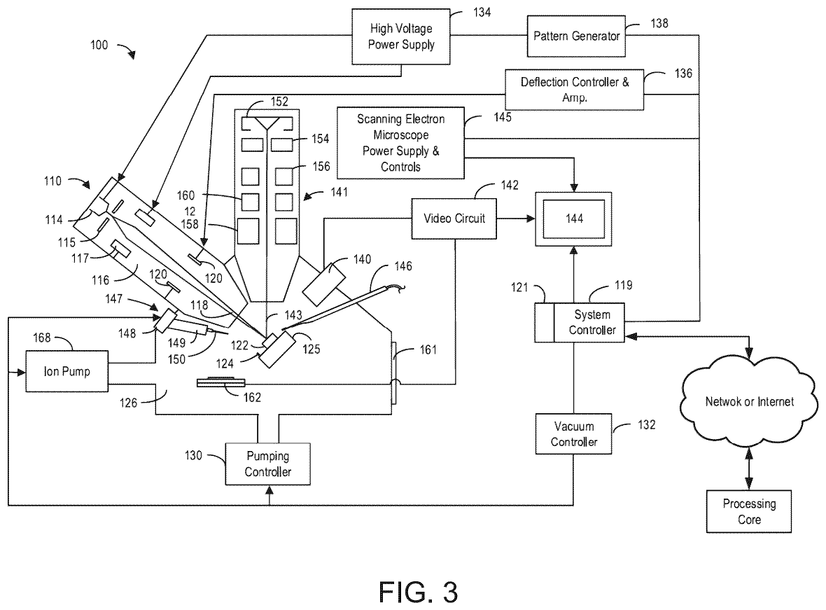

The images are acquired utilising a charged particle microscope. In particular, the images may be acquired using a scanning electron microscope as part of a dual beam system as shown in FIG. 3.

Finally, the endpoint of the milling is determined. The endpoint is based on a relative spatial characteristic between the two or more lines of the plurality of lines.

The images acquired are analysed, either using an algorithm or manually, to determine if the relative spatial characteristic satisfies a preestablished condition, e.g., either of the same depth/height or equidistant/distance ratio.

If the condition is met, then the material removal is halted. If not, additional material removal occurs.

Once the endpoint is reached, processing of the lamella may be complete or further processing may occur, for example an opposing side of the lamella may then be processed.

Where further processing occurs, the application of LIT lines and material removal may be repeated one or more times in order to provide effective imaging of the ROI.

Alternatively, a first ROI and endpoint process may be performed using a high energy ion beam, such as 30 keV, where the material removal is halted at the edge of the first ROI using the techniques disclosed herein.

Subsequently, a second ROI may be targeted using a lower ion beam energy and additional or the same endpoint lines on the top surface. The second ROI may be smaller than the first so that a thinner lamella is formed using lower energy ions. In general, the line-based endpoint detection techniques disclosed herein may be used repetitively on a single sample to obtain a desired lamella.

In the method of the invention, the endpoint may be determined when two adjacent lines of the plurality of lines have a same depth in the newly exposed surface of the sample, wherein the depth of the lines is the relative spatial characteristic.

Alternatively, the endpoint may be determined when a distance between two lines of the plurality of lines equals a predetermined distance, wherein the distance between the two lines is the relative spatial characteristic. For example, wherein the predetermined distance is based on an edge location of the region of interest (ROI), and wherein at least two lines of the plurality of lines are formed on the newly exposed surface to be separated by the predetermined distance at the edge location of the ROI.

The endpoint may also be determined by determining a ratio of distances between at least two lines of the plurality of lines.

It should be noted that the determination of the endpoint may be performed manually or may be performed by analysing the acquired images using a machine learning algorithm to determine the endpoint based on the relative spatial characteristic as defined above.

The application also provides an apparatus at least includes an ion beam column coupled to provide an ion beam; an electron beam column coupled to provide an electron beam, a sample arranged to receive the ion and electron beams, and a controller coupled to control the ion and electron beams. The controller includes or is coupled to nontransitory computer readable medium storing instructions that, when executed by the controller, cause the apparatus to:
remove, with the ion beam, a surface of a sample to provide a newly exposed surface;
determine a region of interest on the newly exposed surface;
form, with the ion beam, a plurality of lines on the newly exposed surface of the sample;
remove, a plurality of times with the ion beam, material from a working surface of the sample, the working surface different than the top surface;
image, a plurality of times with the electron beam, the sample a plurality of times to at least capture the plurality of lines, each of the occurring plurality of times occurring between at least one removal step; and
determine an endpoint based on a relative spatial characteristic between two or more lines of the plurality of lines.

The description will clearly enable one skilled in the art to make and use the invention, and describe several embodiments, adaptations, variations, alternatives and uses of the invention. As used herein, the terms “about” or “approximately” for any numerical values or ranges indicate a suitable dimensional tolerance that allows the part or collection of components to functions for its intended purpose as described.

For the avoidance of doubt, in this specification when we use the term “comprising” or “comprises” we mean that the feature being described must contain the listed component(s) but may optionally contain additional components. When we use the term “consisting essentially of” or “consists essentially of” we mean that the feature being described must contain the listed component(s) and may also contain other components provided that any components do not affect the essential properties of the feature. When we use the term “consisting of” or “consists of” we mean that the feature being described must contain the listed component(s) only.

As used herein, the term “at least one” is intended to mean that the compound comprises one or more of the features referred to. In particular, one, two, three or four of the features referred to, from one to four or from one to three.

As used in this application and in the claims, the singular forms “a,” “an,” and “the”include the plural forms unless the context clearly dictates otherwise.

Additionally, the term “includes” means “comprises.”

Further, the term “coupled” does not exclude the presence of intermediate elements between the coupled items.

The systems, apparatus, and methods described herein should not be construed as limiting in any way. Instead, the present disclosure is directed toward all novel and non-obvious features and aspects of the various disclosed embodiments, alone and in various combinations and sub-combinations with one another. The disclosed systems, methods, and apparatus are not limited to any specific aspect or feature or combinations thereof, nor do the disclosed systems, methods, and apparatus require that any one or more specific advantages be present, or problems be solved. Any theories of operation are to facilitate explanation, but the disclosed systems, methods, and apparatus are not limited to such theories of operation.

Although the operations of some of the disclosed methods are described in a particular, sequential order for convenient presentation, it should be understood that this manner of description encompasses rearrangement, unless a particular ordering is required by specific language set forth below. For example, operations described sequentially may in some cases be rearranged or performed concurrently.

Moreover, for the sake of simplicity, the attached figures may not show the various ways in which the disclosed systems, methods, and apparatus can be used in conjunction with other systems, methods, and apparatus. Additionally, the description sometimes uses terms like “produce” and “provide” to describe the disclosed methods. These terms are high-level abstractions of the actual operations that are performed. The actual operations that correspond to these terms will vary depending on the particular implementation and are readily discernible by one of ordinary skill in the art.

In some examples, values, procedures, or apparatuses are referred to as “lowest”, “best”, “minimum,” or the like. It will be appreciated that such descriptions are intended to indicate that a selection among many used functional alternatives can be made, and such selections need not be better, smaller, or otherwise preferable to other selections.

As noted above, the use of LIT for BEOL type structures is typically not possible due to sample structure.

A solution to this problem is the method and apparatus as defined in this application and is explained in more detail below with reference to the figures.

FIG. 3 is an illustration of a dual beam system 100 for performing line-based endpoint determination in accordance with an embodiment of the present disclosure.

System 100 includes a vertically mounted scanning electron microscope (SEM) column and a focused ion beam (FIB) column mounted at an angle with respect to the SEM column. The system 100 may be used to image and alter, e.g., mill or deposit onto samples. In some embodiments, system 100 is used to form lamella for imaging in a transmission electron microscope, for example, where the lamella is to have a region of interest (ROI) located therein.

However, to form the lamella to include the ROI, milling endpoints are needed to help guide the milling operation, where the endpoints help determine when to stop the milling process. One technique to use for endpoint determination is to include two or more lines on a top surface of the sample, where a relative spatial characteristic between the two or more lines is monitored.

When the relative spatial characteristic equals a threshold value or pre-established condition, the endpoint has been reached or will be reached in a subsequent mill process. While an example of suitable hardware is provided below, the disclosed techniques are not limited to being implemented in any particular type of hardware.

A scanning electron microscope (SEM) 141, along with power supply and control unit 145, is provided with the dual beam system 100. An electron beam 143 is emitted from a cathode 152 by applying voltage between cathode 152 and an anode 154. Electron beam 143 is focused to a fine spot by means of a condensing lens 156 and an objective lens 158. Electron beam 143 is scanned two-dimensionally on the specimen by means of a deflection coil 160. Operation of condensing lens 156, objective lens 158, and deflection coil 160 is controlled by power supply and control unit 145.

Electron beam 143 can be focused onto sample 122, which is on movable X-Y stage 125 within lower chamber 126. When the electrons in the electron beam strike sample 122, secondary electrons are emitted. These secondary electrons are detected by secondary electron detector 140. STEM detector 162, located beneath the TEM sample holder 124 and the stage 125, can collect electrons that are transmitted through the sample mounted on the TEM sample holder as discussed above.

Dual beam system 100 also includes focused ion beam (FIB) system 110 which comprises an evacuated chamber having an upper neck portion 112 within which are located an ion source 114 and a focusing column 116 including extractor electrodes and an electrostatic optical system. The axis of focusing column 116 is tilted with respect to the axis of the electron column, such as by 52° in some embodiments. The ion column 112 includes an ion source 114, an extraction electrode 115, a focusing element 117, deflection elements 120, and a focused ion beam 118. Focused ion beam 118 passes from ion source 114 through focusing column 116 and between electrostatic deflection means schematically indicated at 120 toward substrate 122, which comprises, for example, a semiconductor device positioned on movable X-Y stage 125 within lower chamber 126.

Stage 125 can preferably move in a horizontal plane (X and Y axes) and vertically (Z axis). Stage 125 can also tilt approximately sixty (60) degrees and rotate about the Z axis. In some embodiments, a separate TEM sample stage (not shown) can be used. Such a TEM sample stage will also preferably be moveable in the X, Y, and Z axes. A door 161 is opened for inserting substrate 122 onto X-Y stage 125 and also for servicing an internal gas supply reservoir, if one is used.

An ion pump 168 is employed for evacuating neck portion 112. The chamber 126 is evacuated with turbomolecular and mechanical pumping system 130 under the control of vacuum controller 132. The vacuum system provides within chamber 126 a vacuum of between approximately 1×10−7 Torr and 5×10−4 Torr. If an etch assisting, an etch retarding gas, or a deposition precursor gas is used, the chamber background pressure may rise, typically to about 1×10−5 Torr.

The high voltage power supply provides an appropriate acceleration voltage to electrodes in focusing column 116 for energizing and focusing ion beam 118. When it strikes sample 122, material is sputtered, that is physically ejected, from the sample. Alternatively, ion beam 118 can decompose a precursor gas to deposit a material.

High voltage power supply 134 is connected to ion source 114 as well as to appropriate electrodes in ion beam focusing column 116 for forming an approximately 0.5 keV to 60 keV ion beam 118 and directing the same toward a sample. Deflection controller and amplifier 136, operated in accordance with a prescribed pattern provided by pattern generator 138, is coupled to deflection plates 120 whereby ion beam 118 may be controlled manually or automatically to trace out a corresponding pattern on the upper surface of substrate 122. In some systems the deflection plates are placed before the final lens, as is well known in the art. Beam blanking electrodes (not shown) within ion beam focusing column 116 cause ion beam 118 to impact onto blanking aperture (not shown) instead of substrate 122 when a blanking controller (not shown) applies a blanking voltage to the blanking electrode.

In some embodiments, the ion source 114 is a liquid metal ion source that typically provides a metal ion beam of gallium. The source typically is capable of being focused into a sub one-tenth micrometre wide beam at substrate 122 for either modifying the substrate 122 by ion milling, enhanced etch, material deposition, or for the purpose of imaging the substrate 122. In other embodiments, the ion source 114 is a plasma-based ion source capable of providing ion beam 118 formed of a variety of ions, such as Xenon, Oxygen, Nitrogen, Argon, etc., and can be used for the same purposes as above, such as ion milling, enhanced etching, material deposition, and/or imaging.

A charged particle detector 140, such as an Everhart Thornley or multi-channel plate, used for detecting secondary ion or electron emission is connected to a video circuit 142 that supplies drive signals to video monitor 144 and receiving deflection signals from a system controller 119. The location of charged particle detector 140 within lower chamber 126 can vary in different embodiments. For example, a charged particle detector 140 can be coaxial with the ion beam and include a hole for allowing the ion beam to pass. In other embodiments, secondary particles can be collected through a final lens and then diverted off axis for collection.

A micromanipulator 147 can precisely move objects within the vacuum chamber. Micromanipulator 147 may comprise precision electric motors 148 positioned outside the vacuum chamber to provide X, Y, Z, and theta control of a portion 149 positioned within the vacuum chamber. The micromanipulator 147 can be fitted with different end effectors for manipulating small objects.

A gas delivery system 146 extends into lower chamber 126 for introducing and directing a gaseous vapor toward substrate 122. For example, iodine can be delivered to enhance etching, or a metal organic compound can be delivered to deposit a metal.

System controller 119 controls the operations of the various parts of dual beam system 100. Through system controller 119, a user can cause ion beam 118 or electron beam 143 to be scanned in a desired manner through commands entered into a conventional user interface (not shown). Alternatively, system controller 119 may control dual beam system 110 in accordance with programmed instructions stored in a memory 121. In some embodiments, dual beam system 100 incorporates image recognition software to automatically identify regions of interest, and then the system can manually or automatically determine a processing endpoint in accordance with the disclosure. In other embodiments, acquired images may be processed by a machine learning algorithm or neural network to determine the endpoint through image segmentation and analysis, for example. In such an embodiment, the machine learning algorithm or the neural network model may be performed by controller 119 or by a processing core coupled via a network or the internet.

In operation, the controller 119 automatically or via user control may establish lines on a top surface of sample 122, which are then used to determine when to stop processing the sample 122 with respect to lamella formation. For example, an ROI may be mapped onto the top surface of the sample 122, which may be an outline for the lamella or an area within the lamella, then two or more lines may be formed on the top surface to establish where the edges of the ROI are located. These lines, which may be trenches milled into the surface or protrusions deposited on the top surface, may be arranged so that a relative spatial characteristic between at least two of the lines indicates an endpoint to material removal. In some embodiments, the endpoint may be an edge of the lamella, but in other embodiments the endpoint may be an edge of the ROI. The lamella may then be used for further analysis, such as in a transmission electron microscope (TEM). In some embodiments, the relative spatial characteristic may be a depth or height of two adjacent lines. In other embodiments, the relative spatial characteristic may be a distance between two or more of the lines, or a ratio of such distances. In both embodiments, however, the lines are formed on the top surface in such a way where the depths/heights or distances are aligned to a desired, pre-established endpoint, such as the edge of the ROI. See FIGS. 2 and 3 for examples.

For further illustration, after the lines are formed on the top surface of sample 122, the ion beam 118 is used to remove sample material to uncover/form a side (e.g., working surface) of the sample in order to form a lamella that includes the desired ROI. The working surface may be at a normal angle to the top surface where the lines are formed, or some acute or obtuse angle thereto. The removal of the material may be by ion beam milling or ion beam assisted etching, or a combination thereof. In some embodiments, the energy of the ion beam may be adjusted as the working face moves closer to the desired endpoint, such as from 30 keV down to 0.5 keV, for example. In other embodiments, a first ROI and endpoint process may be performed using a high energy ion beam, such as 30 keV, where the material removal is halted at the edge of the first ROI using the techniques disclosed herein. Subsequently, a second ROI may be targeted using a lower ion beam energy and additional or the same endpoint lines on the top surface. The second ROI may be smaller than the first so that a thinner lamella is formed using lower energy ions. In general, the line-based endpoint detection techniques disclosed herein may be used repetitively on a single sample 122 to obtain a desired lamella.

As sample material is removed, images are acquired of the working face. These images are then analyzed, either using an algorithm or manually, to determine if the relative spatial characteristic satisfies the preestablished condition, e.g., either of the same depth/height or equidistant/distance ratio. If not, additional material removal occurs. In some embodiments, if the condition is met, then the material removal is halted. In other embodiments, the condition being satisfied indicates that an additional material removal step will provide the desired endpoint. This material removal step can be at a same or lower milling energy, for example, than the previous material removal steps. Once the endpoint is reached, processing of the lamella may be complete, or an opposing side of the lamella may then be processed.

### Disclosure Paragraphs

Paragraph 1 is a method for preparing a sample for analysis by a charged particle microscope, including: removing material from a surface of a sample to provide a newly exposed surface; determining a region of interest (ROI) on the newly exposed surface of the sample; forming a plurality of lines on the newly exposed surface of the sample; removing, a plurality of times, material from a working surface of the sample, where the working surface of the sample is different than the newly exposed surface; imaging the working surface of the sample a plurality of times to at least capture the plurality of lines; and determining an endpoint based on a relative spatial characteristic between two or more lines of the plurality of lines.

Paragraph 2 includes the subject matter of Paragraph 1, and further specifies that removing material from the top surface of a sample includes: removing material parallel to the top surface or at an angle to the top surface.

Paragraph 3 includes the subject matter of any of Paragraphs 1-2, and further specifies that determining the region of interest includes applying a map to the newly exposed surface. (i.e. CAD map).

Paragraph 4 includes the subject matter of any of Paragraphs 1-3, and further specifies that determining an endpoint based on a relative spatial characteristic between two or more lines of the plurality of lines includes: determining when two adjacent lines of the plurality of lines have a same depth in the newly exposed surface of the sample, wherein the depth of the lines is the relative spatial characteristic.

Paragraph 5 includes the subject matter of any of Paragraphs 1-4, and further specifies that determining an endpoint based on a relative spatial characteristic between two or more lines of the plurality of lines includes: determining when a distance between two lines of the plurality of lines equals a predetermined distance, wherein the distance between the two lines is the relative spatial characteristic.

Paragraph 6 includes the subject matter of any of Paragraphs 1-5, and further specifies that the predetermined distance is based on an edge location of the region of interest (ROI), and wherein at least two lines of the plurality of lines are formed on the newly exposed surface to be separated by the predetermined distance at the edge location of the ROI.

Paragraph 7 includes the subject matter of any of Paragraphs 1-7, and further specifies that determining an endpoint based on a relative spatial characteristic between two or more lines of the plurality of lines includes: determining a ratio of distances between at least two lines of the plurality of lines.

Paragraph 8 includes the subject matter of any of Paragraphs 1, and further specifies that determining an endpoint based on a relative spatial characteristic between two or more lines of the plurality of lines includes analysing the acquired images using a machine learning algorithm to determine the endpoint based on the relative spatial characteristic.

Paragraph 9 includes the subject matter of any of Paragraphs 1-8, and further specifies that forming the plurality of lines on the newly exposed surface of the sample includes: forming a series of lines arranged parallel and laterally offset, wherein at least one end of each line of the series of lines overlaps with at least one laterally offset line of the series of lines, and wherein a depth of each line where the lines overlap is the same.

Paragraph 10 includes the subject matter of any of Paragraphs 1-9, and further specifies that forming the series of lines includes forming each line of the series of lines using the same ion beam parameters.

Paragraph 11 includes the subject matter of any of Paragraphs 1-10, and further specifies that forming the plurality of lines on a newly exposed surface of the sample includes: forming a plurality of lines arranged at angles to one another, wherein a distance between at least two sets of lines is known at least at one location along their extent.

Paragraph 12 includes the subject matter of any of Paragraphs 1-11, and further specifies that removing, a plurality of times, material from a working surface of the sample, where the working surface of the sample is different than the newly exposed surface includes: milling the material with a focused ion beam.

Paragraph 13 includes the subject matter of any of Paragraphs 1-12, and further specifies that imaging the sample a plurality of times to at least capture a profile of the plurality of lines includes: acquiring an electron beam image of the working surface.

Paragraph 14 includes the subject matter of any of Paragraphs 1-13, and further specifies that imaging, a plurality of times, the sample to at least capture a profile of the plurality of lines includes: imaging the sample while removing material, or imaging the sample between removing material.

Paragraph 15 includes the subject matter of any of Paragraphs 1-14, and further specifies that forming a plurality of lines on the newly exposed surface of the sample includes: forming the plurality of lines on the newly exposed surface of the sample so that the relative spatial characteristic aligns with an edge of the region of interest determined in (ii).

Paragraph 16 includes the subject matter of any of Paragraphs 1-15, and further specifies that forming the plurality of lines on the newly exposed surface of the sample so that the relative spatial characteristic aligns with an edge of the region of interest determined in (ii) includes: forming at least two of the lines of the plurality of lines on the newly exposed surface so that an area of adjacent overlap aligns with the edge of the region of interest determined in (ii).

Paragraph 17 includes the subject matter of any of Paragraphs 1-16, and further specifies that forming the plurality of lines on the newly exposed surface of the sample so that the relative spatial characteristic aligns with an edge of the region of interest determined in (ii) includes: forming at least two of the lines of the plurality of lines on the newly exposed surface at different respective angles to a third line; and determining a distance between the at least two lines at the edge of the region of interest determined in (ii).

Paragraph 18 includes the subject matter of any of Paragraphs 1-17, and further specifies that at least one of the method steps (i) to (vi) may be repeated one or more times.

Paragraph 19 is an apparatus comprising: an ion beam column coupled to provide an ion beam; an electron beam column coupled to provide an electron beam; a sample arranged to receive the ion and electron beams; and a controller coupled to control the ion and electron beams, wherein the controller includes or is coupled to non-transitory computer readable medium storing instructions that, when executed by the controller, cause the apparatus to: remove, with the ion beam, material from a newly exposed surface of a sample; determine a ROI on the newly exposed surface of the sample; form, with the ion beam, a plurality of lines on the newly exposed surface of the sample; remove, a plurality of times with the ion beam, material from a working surface of the sample, where the working surface is different than the newly exposed surface; image, a plurality of times with the electron beam, the sample to at least capture the plurality of lines; and determine an endpoint based on a relative spatial characteristic between two or more lines of the plurality of lines.

Paragraph 20 includes the subject matter of Paragraph 19, and further specifies that the code executed to determine an endpoint based on a relative spatial characteristic between two or more lines of the plurality of lines includes code that, when executed by the controller, causes the apparatus to: determine when two adjacent lines of the plurality of lines have a same depth in the newly exposed surface of the sample, wherein the depth of the lines is the relative spatial characteristic.

Paragraph 21 includes the subject matter of any of Paragraphs 19-20, and further specifies that the code executed to determine an endpoint based on a relative spatial characteristic between two or more lines of the plurality of lines includes code that, when executed by the controller, causes the apparatus to: determine when a distance between two lines of the plurality of lines equals a predetermined distance, wherein the distance between the two lines is the relative spatial characteristic.

Paragraph 22 includes the subject matter of any of Paragraphs 19-21, and further specifies that the predetermined distance is based on an edge location of a region of interest (ROI), and wherein at least two lines of the plurality of lines are formed on the newly exposed surface to be separated by the predetermined distance at the edge location of the ROI.

Paragraph 23 includes the subject matter of any of Paragraphs 19-22, and further specifies that the code executed to determine an endpoint based on a relative spatial characteristic between two or more lines of the plurality of lines includes code that, when executed by the controller, causes the apparatus to: analyse the acquired images using a machine learning algorithm to determine the endpoint based on the relative spatial characteristic.

Paragraph 24 includes the subject matter of any of Paragraphs 19-23, and further specifies that the code executed to form a plurality of lines on a newly exposed surface includes code that, when executed by the controller, causes the apparatus to: form a series of lines arranged parallel and laterally offset, wherein at least one end of each line of the series of lines overlaps with at least one laterally offset line of the series of lines, and wherein a depth of each line where the lines overlap is the same.

Paragraph 25 includes the subject matter of any of Paragraphs 19-24, and further specifies that the code executed to form a plurality of lines on a newly exposed surface includes code that, when executed by the controller, causes the apparatus to: form a plurality of lines arranged at angles to one another, wherein a distance between at least two sets of lines is known at least at one location along their extent.

Paragraph 26 includes the subject matter of any of Paragraphs 19-25, and further specifies that the code executed to form a plurality of lines on a newly exposed surface includes code that, when executed by the controller, causes the apparatus to: form the plurality of lines on the newly exposed surface of the sample so that the relative spatial characteristic aligns with an edge of a region of interest.

In view of the many possible embodiments to which the principles of the disclosed technology may be applied, it should be recognized that the illustrated embodiments are only preferred examples and should not be taken as limiting the scope of the disclosure. We claim as our invention all that comes within the scope and spirit of the appended claims.

We claim:

1. A method for preparing a sample for analysis by a charged particle microscope comprising:
(i) removing material from a surface of the sample to provide a newly exposed surface;
(ii) determining a region of interest (ROI) on the newly exposed surface of the sample;
(iii) forming a plurality of lines on the newly exposed surface of the sample;
(iv) removing, a plurality of times, material from a working surface of the sample, wherein the working surface of the sample is different than the newly exposed surface;
(v) imaging the working surface of the sample, a plurality of times, to at least capture the plurality of lines; and
(vi) determining an endpoint based on a relative spatial characteristic between two or more lines of the plurality of lines.

2. The method of claim 1, wherein removing material from the top surface of the sample includes: removing material parallel to the top surface or at an angle to the top surface.

3. The method of claim 1, wherein determining the region of interest includes applying a map to the newly exposed surface.

4. The method of claim 1, wherein determining an endpoint based on a relative spatial characteristic between two or more lines of the plurality of lines includes: determining when two adjacent lines of the plurality of lines have a same depth in the newly exposed surface of the sample, wherein the depth of the lines is the relative spatial characteristic.

5. The method of claim 1, wherein determining an endpoint based on a relative spatial characteristic between two or more lines of the plurality of lines includes: determining when a distance between two lines of the plurality of lines equals a predetermined distance, wherein the distance between the two lines is the relative spatial characteristic.

6. The method of claim 5, wherein the predetermined distance is based on an edge location of the region of interest (ROI), and wherein at least two lines of the plurality of lines are formed on the newly exposed surface to be separated by the predetermined distance at the edge location of the ROI.

7. The method of claim 1, wherein determining an endpoint based on a relative spatial characteristic between two or more lines of the plurality of lines includes: determining a ratio of distances between at least two lines of the plurality of lines.

8. The method of claim 1, wherein determining an endpoint based on a relative spatial characteristic between two or more lines of the plurality of lines includes: analysing the plurality of images using a machine learning algorithm to determine the endpoint based on the relative spatial characteristic.

9. The method of claim 1, wherein forming the plurality of lines on the newly exposed surface of the sample includes: forming a series of lines arranged parallel and laterally offset, wherein at least one end of each line of the series of lines overlaps with at least one laterally offset line of the series of lines, and wherein a depth of each line where the lines overlap is the same.

10. The method of claim 9, wherein forming the series of lines includes forming each line of the series of lines using the same ion beam parameters.

11. The method of claim 1, wherein forming the plurality of lines on a newly exposed surface of the sample includes: forming a plurality of lines arranged at angles to one another, wherein a distance between at least two sets of lines is known at least at one location along their extent.

12. The method of claim 1, wherein removing, a plurality of times, material from a working surface of the sample, where the working surface of the sample is different than the newly exposed surface includes: milling the material with a focused ion beam.

13. The method of claim 1, wherein imaging the sample a plurality of times to at least capture a profile of the plurality of lines includes: acquiring an electron beam image of the working surface.

14. The method according to claim 1, wherein imaging, a plurality of times, the sample to at least capture a profile of the plurality of lines includes imaging the sample while removing material or imaging the sample between removing material.

15. The method of claim 1, wherein forming a plurality of lines on the newly exposed surface of the sample includes forming the plurality of lines on the newly exposed surface of the sample so that the relative spatial characteristic aligns with an edge of the region of interest determined in (ii).

16. The method of claim 15, wherein forming the plurality of lines on the newly exposed surface of the sample so that the relative spatial characteristic aligns with an edge of the region of interest determined in (ii) includes: forming at least two of the lines of the plurality of lines on the newly exposed surface so that an area of adjacent overlap aligns with the edge of the region of interest determined in (ii).

17. The method of claim 15, wherein forming the plurality of lines on the newly exposed surface of the sample so that the relative spatial characteristic aligns with an edge of the region of interest determined in (ii) includes: forming at least two of the lines of the plurality of lines on the newly exposed surface at different respective angles to a third line; and determining a distance between the at least two lines at the edge of the region of interest determined in (ii).

18. The method of claim 1, wherein at least one of the steps (i) to (vi) is repeated one or more times.

19. An apparatus comprising:
an ion beam column coupled to provide an ion beam;
an electron beam column coupled to provide an electron beam;
a sample arranged to receive the ion beam and the electron beam; and
a controller coupled to control the ion beam and the electron beam, wherein the controller includes or is coupled to non-transitory computer readable medium storing controller-executable instructions that, when executed by the controller, cause the apparatus to:
remove, with the ion beam, material from a newly exposed surface of a sample;
determine a region of interest (ROI) on the newly exposed surface of the sample;
form, with the ion beam, a plurality of lines on the newly exposed surface of the sample;
remove, a plurality of times with the ion beam, material from a working surface of the sample, where the working surface is different than the newly exposed surface;
image, a plurality of times with the electron beam, the sample to at least capture the plurality of lines; and
determine an endpoint based on a relative spatial characteristic between two or more lines of the plurality of lines.

20. The apparatus of claim 19, wherein the controller-executable instructions executed to determine an endpoint based on a relative spatial characteristic between two or more lines of the plurality of lines includes controller-executable instructions that, when executed, cause the apparatus to determine when two adjacent lines of the plurality of lines have a same depth in the newly exposed surface of the sample, wherein the depth of the lines is the relative spatial characteristic.

21. The apparatus of claim 19, wherein the controller-executable instructions executed to determine an endpoint based on a relative spatial characteristic between two or more lines of the plurality of lines include controller-executable instructions that cause the apparatus to determine when a distance between two lines of the plurality of lines equals a predetermined distance, wherein the distance between the two lines is the relative spatial characteristic.

22. The apparatus of claim 21, wherein the predetermined distance is based on an edge location of the ROI, and wherein at least two lines of the plurality of lines are formed on the newly exposed surface to be separated by the predetermined distance at the edge location of the ROI.

23. The apparatus of claim 19, wherein the controller-executable instructions executed to determine an endpoint based on a relative spatial characteristic between two or more lines of the plurality of lines includes controller-executable instructions that, when executed, cause the apparatus to analyse the acquired images using a machine learning algorithm to determine the endpoint based on the relative spatial characteristic.

24. The apparatus of claim 19, wherein the controller-executable instructions executed to form a plurality of lines on a newly exposed surface includes controller-executable instructions that, when executed, cause the apparatus to: form a series of lines arranged parallel and laterally offset, wherein at least one end of each line of the series of lines overlaps with at least one laterally offset line of the series of lines, and wherein a depth of each line where the lines overlap is the same.

25. The apparatus of claim 19, wherein the controller-executable instructions executed to form a plurality of lines on a newly exposed surface includes controller-executable instructions that, when executed, cause the apparatus to: form a plurality of lines arranged at angles to one another, wherein a distance between at least two sets of lines is known at least at one location along their extent.

26. The apparatus of claim 19, wherein the controller-executable instructions executed to form a plurality of lines on a newly exposed surface includes controller-executable instructions that, when executed, cause the apparatus to form the plurality of lines on the newly exposed surface of the sample so that the relative spatial characteristic aligns with an edge of a region of interest.
